(19) United States
(12) Patent Application Publication
(10) Pub. No.: US 2024/0168137 A1
(43) Pub. Date: May 23, 2024

(54) LASER EMITTER AND OPTICAL RANGING APPARATUS

(71) Applicant: DENSO CORPORATION, Kariya-city (JP)

(72) Inventor: MASATO NAKAJIMA, Kariya-city (JP)

(21) Appl. No.: 18/428,065

(22) Filed: Jan. 31, 2024

Related U.S. Application Data
(63) Continuation of application No. PCT/JP2022/028335, filed on Jul. 21, 2022.

(30) Foreign Application Priority Data
Aug. 31, 2021 (JP) 2021-140693

(51) Int. Cl. G01S 7/484; G01S 17/10; H01S 5/042; H02M 3/158

(52) U.S. Cl. CPC G01S 7/484; G01S 17/10; H01S 5/0428; H02M 3/1584

(57) ABSTRACT

A laser emitter includes a booster circuit, a drive circuit, a second diode, and a light emission driver. The booster circuit has a coil, a first switch, a first diode, and a capacitor. The booster circuit raises a DC voltage supplied by a DC power supply. The first switch executes switchover between a conductive state and a non-conductive state of the coil. The first diode is connected in forward bias. The drive circuit has a laser diode and a second switch. The laser diode is supplied by the DC voltage raised by the booster circuit. The second switch executes switchover between a conductive state or non-conductive state of the laser diode. The second diode is connected to the first switch in series, and is connected in forward bias. The light emission driver controls the booster circuit and the drive circuit.

### CROSS REFERENCE TO RELATED APPLICATIONS

The present application is a continuation application of International Patent Application No. PCT/JP2022/028335 filed on Jul. 21, 2022, which designated the U.S. and claims the benefit of priority from Japanese Patent Application No. 2021-140693 filed on Aug. 31, 2021. The entire disclosures of all of the above applications are incorporated herein by reference.

### TECHNICAL FIELD

The present disclosure relates to a laser emitter and an optical ranging apparatus.

### BACKGROUND

A ranging apparatus may measure a distance to an object by emitting a laser beam toward the object and then receiving the reflection light from the object, and measuring the time from irradiation to optical reception. In order to improve ranging performance, it may be required to irradiate a high-power laser beam. In order to irradiate a high-power laser beam, it may be necessary to apply a high voltage to the laser diode that emits the laser beam. A booster circuit may be adopted to apply a high voltage to the laser diode.

### SUMMARY

The present disclosure describes a laser emitter and an optical ranging apparatus, each of which includes a booster circuit, a drive circuit, and a light emission driver.

### BRIEF DESCRIPTION OF DRAWINGS

Objects, features and advantages of the present disclosure will become more apparent from the following detailed description made with reference to the accompanying drawings. In the drawings:

FIG. 1 illustrates a structure of an optical ranging apparatus;

FIG. 2 illustrates a circuitry structure of a laser emitter according to a first embodiment;

FIG. 3 is an equivalent circuit diagram of a booster circuit and a drive circuit for illustrating secondary light emission;

FIG. 4 is a timing chart of a light emission process;

FIG. 5 illustrates a circuitry structure of a laser emitter according to a second embodiment; and

FIG. 6 illustrates a circuitry structure of a laser emitter according to a third embodiment.

### DETAILED DESCRIPTION

In order to improve ranging performance of a ranging apparatus, it may be required to irradiate a high-power laser beam. In order to irradiate a high-power laser beam, it may be necessary to apply a high voltage to the laser diode that emits the laser beam. A booster circuit may be adopted to apply a high voltage to the laser diode. A laser emitter may include a chopper booster circuit.

When a large current flows through a laser diode for a short period of time, parasitic inductance of the wiring may cause the laser diode to emit light unintentionally after the desired light emission. This is because a body diode of a switching transistor for switching between a conductive state and a non-conductive state of the coil included in the chopper booster circuit forms a path through which current flows to the laser diode. If the laser diode emits light unintentionally, the ranging precision may decrease.

According to a first aspect of the present disclosure, a laser emitter includes a booster circuit, a drive circuit, a second diode, and a light emission driver. The booster circuit has a coil, a first switch, a first diode, and a capacitor. The booster circuit raises a DC voltage supplied by a DC power supply. The first switch executes switchover between a conductive state and a non-conductive state of the coil. The first diode is connected in forward bias to the DC power supply. The drive circuit has a laser diode and a second switch. The laser diode is supplied with the DC voltage raised by the booster circuit. The second switch executes switchover between a conductive state or non-conductive state of the laser diode. The second diode is connected to the first switch in series, and is connected in forward bias to the DC power supply. The light emission driver controls the booster circuit and the drive circuit.

According to such a laser emitter described above, the second diode is connected in the reverse direction with respect to the direction of current flow in the current path caused by parasitic inductance of the wiring, which unintentionally emits light after the desired light emission. Therefore, with the second diode, the flow of current in the circuit is blocked, thereby suppressing unintended light emission from the laser diode. Consequently, it is possible to mitigate the decrease in ranging precision.

According to a second aspect of the present disclosure, an optical ranging apparatus includes a laser emitter, a light receiver, and a calculator. The laser emitter includes a booster circuit, a drive circuit, a second diode, and a light emission driver. The booster circuit has a coil, a first switch, a first diode, and a capacitor. The booster circuit raises a DC voltage supplied by a DC power supply. The first switch executes switchover between a conductive state and a non-conductive state of the coil. The first diode is connected in forward bias to the DC power supply. The drive circuit has a laser diode and a second switch. The laser diode is supplied by the DC voltage raised by the booster circuit. The second switch executes switchover between a conductive state or non-conductive state of the laser diode. The second diode is connected to the first switch in series, and is connected in forward bias to the DC power supply. The light emission driver controls the booster circuit and the drive circuit. The light receiver receives reflection light reflected by an object to which laser light is emitted from the laser diode. The calculator calculates a distance to the object based on a time duration from a moment where the laser light is emitted from the laser diode to a moment where the reflection light is received by the light receiver.

Therefore, the optical ranging device with improved ranging precision can be provided by using the laser emitter in which unintended light emission from a laser diode is suppressed.

The following describes multiple embodiments with reference to the drawings. Hereinafter, in the respective embodiments, substantially the same configurations are denoted by identical symbols, and repetitive description will be omitted.

### FIRST EMBODIMENT

The following describes an optical ranging apparatus 100 according to a first embodiment.

(Structure of Optical Ranging Apparatus)

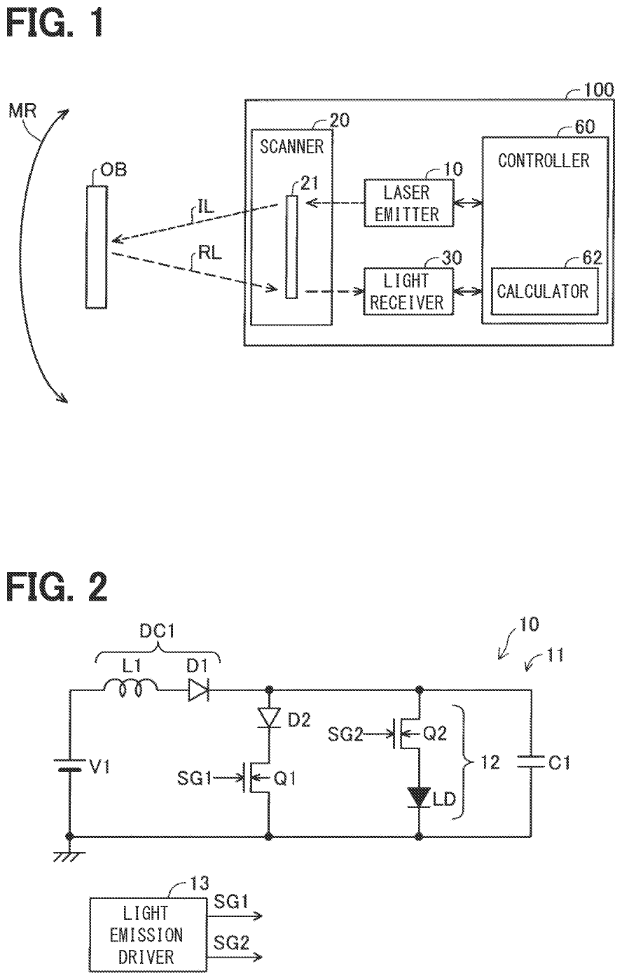

The optical ranging apparatus 100 illustrated in FIG. 1 detects a distance to an object OB by emitting laser light IL and receiving reflection light RL reflected by the object OB. The optical ranging apparatus 100 may be adapted to, for example, a vehicle. In the present embodiment, the optical ranging apparatus 100 is a Light Detection and Ranging (LiDAR) apparatus. The optical ranging apparatus 100 includes a laser emitter 10, a scanner 20, a light receiver 30 and a controller 60. The laser emitter 10 emits laser light IL for ranging. The ranging may also be referred to as distance measurement. The laser light IL may also be referred to as a laser beam.

The controller 60 includes a computer including, for example, a CPU and a memory. The controller 60 controls the operations of the laser emitter 10, the scanner 20 and the light receiver 30. The controller 60 further includes a calculator 62. The calculator 62 calculates the distance to the object OB. The calculator 62 may be operated by the CPU executing a program stored in the memory, or may be operated by an electronic circuit.

The laser emitter 10 includes a laser diode LD for emitting pulsed laser light IL. The laser light IL emitted from the laser diode LD is collimated by a collimating lens (not shown) and enters the scanner 20.

The scanner 20 scans the laser light IL within a predetermined measurement range MR. The scanner 20 includes a mirror 21 and a rotary solenoid (not shown). The mirror 21 reflects the laser light IL, and the rotary solenoid drives the mirror 21. The rotary solenoid repeats a normal rotation and a reverse rotation within a predetermined angle range, so that the laser light IL is scanned within the measurement range MR.

The light receiver 30 receives reflection light RL reflected by the object OB to which the laser light IL is emitted from the laser diode LD. The light receiver 30 outputs a detection signal according to the intensity of the received light to the calculator 62.

The calculator 62 calculates the distance to the object OB by adopting the detection signal received from the light receiver 30. The calculator 62 calculates a distance to the object OB by adopting time of flight (TOF) being a time measured from a moment where the laser light is emitted until a moment where the reflection light is received.

(Circuitry Structure of Laser Emitter)

As shown in FIG. 2, the laser emitter 10 includes a DC power supply V1, a booster circuit 11, a drive circuit 12, a second diode D2, and a light emission driver 13. The booster circuit 11 boosts a DC voltage supplied by the DC power supply V1. The booster circuit 11 includes a coil L1, a first diode D1, a first switch Q1, and a capacitor C1. The first switch Q1 switches between a conductive state and a non-conductive state of the coil L1. The first diode D1 is connected in forward bias to the DC power supply V1 to allow a current flow in a forward direction. In the present embodiment, the coil L1 and the first diode D1 are connected in series to form a first series connector DC1. In the present embodiment, the coil L1 and the first diode D1 are connected in the order of the coil L1 and the first diode D1 from the positive electrode to the negative electrode of the DC power supply V1. An end of the first series connector DC1 is connected to the positive electrode of the DC power supply V1. A capacitor C1 is connected between another end of the first series connector DC1 and the negative electrode of the DC power supply V1.

The second diode D2 is connected in series with the first switch Q1, and is connected in forward bias to the DC power supply V1. In the present embodiment, a connector in which the second diode D2 and the first switch Q1 are connected in series is connected in parallel to the capacitor C1. That is, the second diode D2 and the first switch Q1 are connected between the other end of the first series connector DC1 and the negative electrode of the DC power supply V1. In the present embodiment, the second diode D2 and the first switch Q1 are connected in the order of the second diode D2 and the first switch Q1 from the positive electrode to the negative electrode of the DC power supply V1.

The drive circuit 12 includes a laser diode LD and a second switch Q2. The laser diode LD is supplied by a voltage raised by the booster circuit 11. The second switch Q2 is adopted for executing switchover between the conductive state and the non-conductive state. A connector in which the laser diode LD and the second switch Q2 are connected in series is connected in parallel to the capacitor C1. In the present embodiment, the second switch Q2 and the laser diode LD are connected in the order of the second switch Q2 and the laser diode LD from the positive electrode to the negative electrode of the DC power supply V1. The negative electrode of the DC power supply V1 is connected to the ground. The light emission driver 13 is operated by an electronic circuit, and controls the booster circuit 11 and the drive circuit 12.

In the present embodiment, each of the second switch Q2 and the first switch Q1 is an N-channel insulated gate field effect transistor (IGFET). The gate of the first switch Q1 receives a first gate signal SG1 output from the light emission driver 13. The gate of the second switch Q2 receives a second gate signal SG2 output from the light emission driver 13.

The first switch Q1 switches the coil L1 between the conductive state and the non-conductive state, so that the capacitor voltage VC, which is the voltage of the capacitor C1, becomes higher than the DC voltage of the DC power supply V1. When the second switch Q2 is turned on, the charge accumulated in the capacitor C1 is supplied to the laser diode LD, and the laser diode LD emits light.

The coil L1 and the first diode D1 may be connected in the order of the first diode D1 and the coil L1 from the positive electrode to the negative electrode of the DC power supply V1. The second switch Q2 and the laser diode LD may be connected in the order of the second switch Q2 and the laser diode LD from the positive electrode to the negative electrode of the DC power supply V1. In the present embodiment, the second diode D2 and the first switch Q1 are connected in the order of the first switch Q1 and the second diode D2 from the positive electrode to the negative electrode of the DC power supply V1. Each of the second switch Q2 and the first switch Q1 may be a field-effect transistor (FET) other than IGFET. For example, the FET may be a high electron mobility transistor (HEMT) using gallium nitride (GaN). The HEMT may also be referred to as a heterostructure field-effect transistor (HFET). Furthermore, each of the first switch Q1 and the second switch Q2 may be a bipolar transistor or may be configured by an integrated circuit. Each of the first switch Q1 and the second switch Q2 may be a P-channel IGFET. When the first switch Q1 is a P-channel IGFET, the second diode D2 and the first switch Q1 may be connected in the order of the first switch Q1 and the second diode D2 from the positive electrode to the negative electrode of the DC power supply V1.

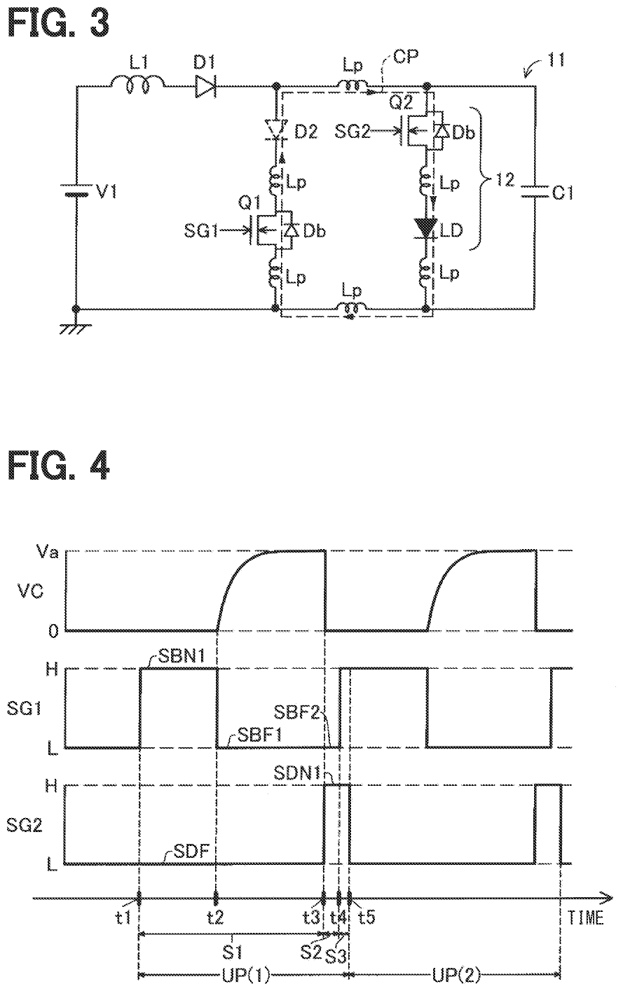

As shown in FIG. 3, the wiring connecting each element of the laser emitter 10 has a parasitic inductance Lp. Furthermore, since each of the second switch Q2 and the first switch Q1 is the IGFET, a body diode Db is formed therein. When the laser emitter 10 does not include the second diode D2, a current path CP flows through the laser diode LD, the body diode Db of the first switch Q1, and the second switch Q2 in the on state. After the second switch Q2 is turned on to control the laser diode LD to emit light, the flow of current through the laser diode LD disappears as the electric charge accumulated in the capacitor C1 disappears. Thus, a current flows through a current path CP through an electromagnetic induction of the parasitic inductance Lp with a rapid increase in the current flow. When a current flows through the current path CP, unintended light emission occurs after the desired light emission. While the desired light emission is also called primary light emission, this unintended light emission is also called secondary light emission. In the secondary light emission, the current flowing through the laser diode LD is smaller than that in the primary light emission. In the present embodiment, the second diode D2 is inserted in the current path CP in a direction opposite to the flow of current that causes the laser diode LD to emit light. This arrangement makes it possible to prevent the secondary light emission. In order to suppress secondary light emission, a method of inserting a damping resistor into the current path CP may also be considered. However, the following situation may occur since a large current flows in the boosting operation. For example, damping resistance may cause heat generation. The circuitry size may become larger since multiple damping resistors may be needed according to the current value. If the damping resistor burns out, the first switch Q1 may suffer from propagation failure due to kickback. According to the present embodiment, it is possible to avoid the above situation in which the damping resistor is inserted.

(Driving Method of Laser Emitter)

The light emission driver 13 executes a light emission process as shown in FIG. 4 in conjunction with a ranging process executed by the controller 60 for measuring a distance to the object OB. In S1, in a period during which the light emission driver 13 outputs a drive-off signal SDF to the second switch Q2, the light emission driver 13 outputs a first boost-off signal SBF1 to the first switch Q1 after the light emission driver 13 outputs a first boost-on signal SBN1 to the first switch Q1.

In the S1, the first gate signal SG1 at a low level Las the drive-off signal SDF is provided to the gate of the second switch Q2 from time t1 to time t3. Then, the second gate signal SG2 at a high level H as the first boost-on signal SBN1 is provided to the gate of the first switch Q1 from time t1 to time t2, and then the second gate signal SG2 at a low level L as the first boost-off signal SBF1 is provided to the gate of the first switch Q1 from the time t2 to time t3.

During the period from the time t1 to the time t2, the first switch Q1 is in an on state, so a current flows through the coil L1. At the time t2, when the first switch Q1 is turned off, the current path through the first switch Q1 is cut off, so that the current flows through the coil L1 according to the inductance of the coil L1. Since the charge is accumulated in the capacitor C1 by the current flowing through the coil L1, the capacitor voltage VC rises to a target voltage Va higher than the DC voltage of the DC power supply V1.

In S2, in a period during which the light emission driver 13 outputs a second boost-off signal SBF2 to the first switch Q1, the light emission driver 13 outputs a first drive-on signal SDN1 to the second switch Q2.

In S2, the first gate signal SG1 at a low level as the second boost-off signal SBF2 is output to the first switch Q1 from the time t3 to time t4. The second gate signal SG2 at a high level H as the first drive-on signal SDN1 is output to the second switch Q2. At the time t3, when the second switch Q2 is turned on, a voltage corresponding to the target voltage Va is applied to the laser diode LD. S1 described above may also be referred to as a first mode, and S2 described above may also be referred to as a second mode.

The charge accumulated in the capacitor C1 flows to the ground via the second switch Q2 and the laser diode LD, which are in an on state. Accordingly, the laser diode LD emits light in a period corresponding to the charge accumulated in the capacitor C1. Therefore, the laser diode LD emits the pulsed laser light IL. The capacitor C1 is discharged, and the capacitor voltage VC becomes 0 volt (V). The current flowing through the laser diode LD is approximately 10 Amperes (A) or more and 100 A or less. The pulse width is about 1 nanosecond (ns) or more and 10 ns or less. The optical output is approximately several 10 Watts (W) or more and several 100 W or less.

In S3, the light emission driver 13 outputs the first gate signal SG1 at a high level H to the gate of the first switch Q1 from time t4 to time t5, and outputs the first gate signal SG1 at a high level H to the second switch Q2. As a result, both the second switch Q2 and the first switch Q1 are turned on. S1 to S3 are executed within the unit period UP. S1 to S3 are repeatedly executed until the controller 60 completes the ranging process. The unit period UP is approximately several microseconds (μs). S3 described above may also be referred to a third mode.

According to the first embodiment described above, the laser emitter 10 includes the booster circuit 11, the drive circuit 12, the second diode D2, and the light emission driver 13. The drive circuit 12 includes the laser diode LD to which the voltage boosted by the booster circuit 11 is supplied. The light emission driver 13 controls the booster circuit 11 and the drive circuit 12. The second diode D2 is connected in series to the first switch Q1 included in the booster circuit 11. The second diode D2 is connected in the reverse direction with respect to the direction of current flow in the secondary emission current path CP, which is generated by the parasitic inductance Lp of the wiring of the laser emitter 10, after the desired light emission. Therefore, the flow of current in the current path CP that causes secondary light emission is blocked by the second diode D2, so that secondary light emission of the laser diode LD can be suppressed. Therefore, the ranging performance of the laser emitter 10 can be enhanced.

The first switch Q1 and the second diode D2 are connected between the other end of the first series connector DC1 and the negative electrode of the DC power supply V1. In the first series connector DC1, the coil L1 and the first diode D1 are connected in series. The light emission driver 13 executes S1 for charging the capacitor C1 once within a unit period UP and S2 for causing the laser diode LD to emit light once within the unit period UP. In S1, in a period during which the light emission driver 13 outputs a drive-off signal SDF to the second switch Q2, the light emission driver 13 outputs a first boost-off signal SBF1 after the light emission driver 13 outputs a first boost-on signal SBN1 to the first switch Q1. In S2, in a period during which the light emission driver 13 outputs a second boost-off signal SBF2 to the first switch Q1, the light emission driver 13 outputs a first drive-on signal SDN1 to the second switch Q2. Thereby, the capacitor voltage VC can be boosted by S1. In S2, the second switch Q2 is turned on, so that the charge in the capacitor C1 flows to the laser diode LD for emitting laser diode LD.

The optical ranging apparatus 100 includes the light receiver 30 and the calculator 62. The light receiver 30 receives the reflection light RL reflected by the object OB to which the laser light IL emitted from the laser diode LD. The calculator 62 calculates the distance to the object OB by adopting a time duration from a moment of emitting the laser light L to a moment of receiving the reflection light RL. Therefore, it is possible to provide the optical ranging apparatus 100 with enhanced ranging precision by adopting the laser emitter 10 that suppresses the secondary light emission.

### SECOND EMBODIMENT

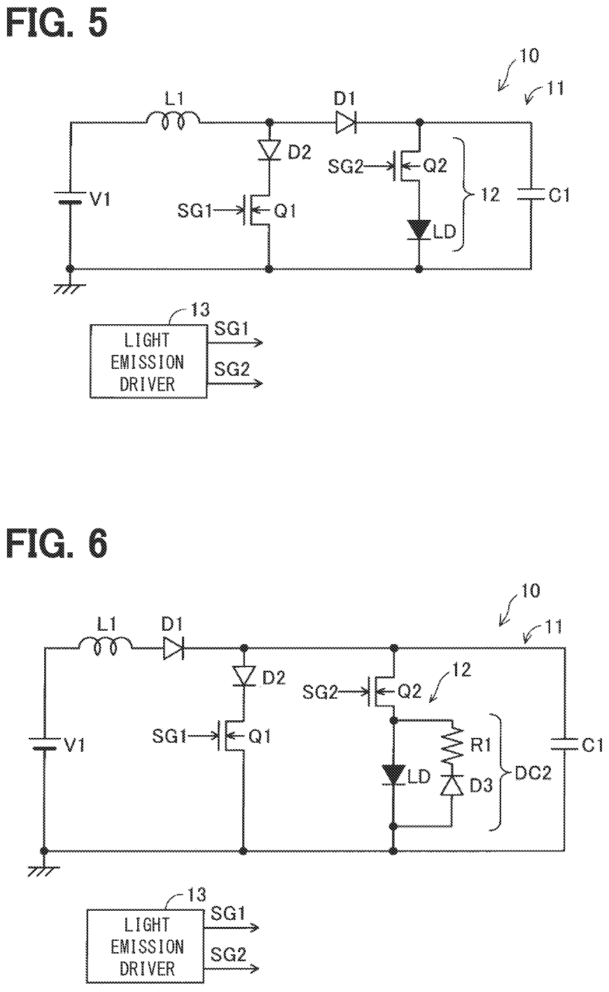

As shown in FIG. 5, in the laser emitter 10 according to the second embodiment, the connection positions of the first switch Q1 and the second diode D2 are different from those in the first embodiment. Specifically, the first switch Q1 and the second diode D2 are connected between the negative electrode of the DC power supply V1 and the connection node between the coil L1 and the first diode D1. Since the other circuit structures are the same as those in the first embodiment, the same structures are denoted by the same reference numerals and the description thereof will be omitted.

The second switch Q2 and the laser diode LD may be connected in the order of the laser diode LD and the second switch Q2 from the positive electrode to the negative electrode of the DC power supply V1. In the present embodiment, the second diode D2 and the first switch Q1 are connected in the order of the first switch Q1 and the second diode D2 from the positive electrode to the negative electrode of the DC power supply V1.

Also in this embodiment, the laser emitter 10 is driven by the same driving method as the driving method according to the first embodiment. S2 may be executed after S1 is executed multiple times in the unit period UP. In this case, the capacitor voltage VC is raised to the target voltage Va by executing S1 multiple times.

According to the second embodiment described above, the first switch Q1 and the second diode D2 are connected between the negative electrode of the DC power supply V1 and the connection node between the coil L1 of the booster circuit 11 and the first diode D1 of the booster circuit 11. The light emission driver 13 executes S1 for charging the capacitor C1 within the unit period UP at least once, and executes S2 for causing the laser diode LD to emit light at least once. Thereby, the capacitor voltage VC can be boosted by S1. In S2, the second switch Q2 is turned on, so that the charge in the capacitor C1 flows to the laser diode LD for emitting laser diode LD.

### THIRD EMBODIMENT

As shown in FIG. 6, the laser emitter 10 according to the third embodiment differs from the laser emitter 10 according to the first embodiment, such that the laser emitter 10 according to the third embodiment includes a second series connector DC2 connected in parallel to the laser diode LD. Since the other circuit structures are the same as those in the first embodiment, the same structures are denoted by the same reference numerals and the description thereof will be omitted. In the second series connector DC2, a third diode D3 as a rectifier and the resistor R1 are connected in series. In the present embodiment, an end of the resistor R1 is connected to an anode of the laser diode LD. A cathode of the third diode D3 is connected to another end of the resistor R1. An anode of the third diode D3 is connected to the cathode of the laser diode LD. The third diode D3 has a rectifying effect that causes a current to flow from the cathode to the anode of the laser diode LD. By having the second series connector DC2, it is possible to enhance the effect of suppressing secondary light emission of the laser diode LD.

After the second switch Q2 is switched to the on state for causing the laser diode LD to emit light, the current does not flow through the laser diode LD as the charge accumulated in the capacitor C1 disappears. Thus, it is possible that a surge voltage occurs at the cathode of the laser diode LD through parasitic inductance Lp. By connecting a third diode D3 in parallel and in reverse direction to the laser diode LD, it is possible to avoid applying surge voltage to the cathode of the laser diode LD. Since the resistor R1 is connected, the value of current flowing through the third diode D3 is limited. Thus, it is possible to suppress the secondary light emission of the laser diode LD. If the laser emitter 10 does not have the resistor R1, the capacitor C1 is charged by a current flowing through the third diode D3 and the second switch Q2 in the on state due to the surge voltage. Subsequently, the laser diode LD executes secondary light emission as the capacitor C1 discharges through the laser diode LD. In the present embodiment, the resistor R1 limits the value of the current through the third diode D3 when the surge voltage occurs. Since the charging of the capacitor C1 is suppressed, the secondary light emission of the laser diode LD can be suppressed.

A reverse conduction part of a transistor may be used as a rectifier instead of the third diode D3. In the case of an IGFET, a body diode of the IGFET may be adopted as the reverse conduction part. Furthermore, in the case of a HEMT using gallium nitride (GaN), the internal structure through which current flows from the source to the drain may be used as the reverse conduction part. The transistor included in the light emission driver 13 or the controller 60 may be adopted as a connected transistor in replacement of the third diode D3.

According to the third embodiment described above, the laser emitter 10 includes the second series connector DC2 connected in parallel to the laser diode LD. In the second series connector DC2, the third diode D3 connected in a reverse direction and the resistor R1 are connected in series. Therefore, by connecting the third diode D3, application of the surge voltage generated by the parasitic inductance Lp to the cathode of the laser diode LD can be suppressed. Since the resistor R1 suppresses charging of the capacitor C1 due to the surge voltage, secondary light emission can be suppressed.

### OTHER EMBODIMENTS

The present disclosure should not be limited to the embodiments or modifications described above, and various other embodiments may be implemented without departing from the scope of the present disclosure. For example, the technical features in each embodiment corresponding to the technical features in the form described in the summary may be used to solve some or all of the above-described problems, or to provide one of the above-described effects. In order to achieve a part or all, replacement or combination can be appropriately performed. In addition, as long as a technical feature is not described as essential in the present specification, the technical feature may be deleted as appropriate.

The light emission driver and the technique according to the present disclosure may be achieved by a dedicated computer provided by constituting a processor and a memory programmed to execute one or more functions embodied by a computer program. Alternatively, the light emission driver and the method described in the present disclosure may be realized by a dedicated computer provided by configuring a processor with one or more dedicated hardware logic circuits. Alternatively, the light emission driver and the method described in the present disclosure may be implemented by one or more special purpose computer, which is configured as a combination of a processor and a memory, which are programmed to perform one or more functions, and a processor which is configured with one or more hardware logic circuits. The computer program may be stored, as instructions to be executed by a computer, in a tangible non-transitory computer-readable medium.

The present disclosure has been described based on examples, but it is understood that the present disclosure is not limited to the examples or structures. The present disclosure encompasses various modifications and variations within the scope of equivalents. In addition, various combinations and forms, and further, other combinations and forms including only one element, or more or less than these elements are also within the scope and the scope of the present disclosure.

The process of the flowchart or the flowchart described in this application includes a plurality of sections, and each section is expressed as, for example, S1. Each section may be divided into several subsections, while several sections may be combined into one section. Furthermore, each section thus configured may be referred to as a device, module, or means.

What is claimed is:

1. A laser emitter comprising:
a booster circuit configured to raise a DC voltage supplied by a DC power supply, the booster circuit including a coil, a first switch, a first diode, and a capacitor, the first switch configured to execute switchover between a conductive state and a non-conductive state of the coil, the first diode being connected in forward bias to the DC power supply;
a drive circuit including a laser diode and a second switch, the laser diode configured to be supplied with the DC voltage raised by the booster circuit, the second switch configured to execute switchover between a conductive state or non-conductive state of the laser diode;
a second diode being connected to the first switch in series, the second diode being connected in forward bias to the DC power supply; and
a light emission driver configured to control the booster circuit and the drive circuit.

2. The laser emitter according to claim 1, wherein:
the booster circuit has a first series connector in which the coil and the first diode are connected in series;
an end of the first series connector is connected to a positive electrode of the DC power supply;
the first switch and the second diode are connected between another end of the first series connector and a negative electrode of the DC power supply;
the light emission driver is further configured to execute a first mode once and a second mode once within a unit period;
the first mode is a mode for charging the capacitor, in which the light emission driver outputs a first boost-on signal to the first switch and then outputs a first boost-off signal to the first switch in a period during which the light emission driver outputs a drive-off signal to the second switch;
the second mode is a mode for causing the laser diode to emit light, in which the light emission driver outputs a first drive-on signal to the second switch in a period during which the light emission driver outputs a second boost-off signal to the first switch; and
the first boost-on signal controls the first switch being turned on to switch the coil into the conductive state, the first boost-off signal controls the first switch being turned off to switch the coil into the non-conductive state, the drive-off signal controls the second switch being turned off to switch the laser diode into the non-conductive state, the first drive-on signal controls the second switch being turned on to switch the laser diode into the conductive state, and the second boost-off signal controls the first switch being turned off to switch the coil into the non-conductive state.

3. The laser emitter according to claim 1, wherein:
the first switch and the second diode are connected between a negative electrode of the DC power supply and a connection node between the coil and the first diode;
the light emission driver is further configured to execute a first mode once or more and a second mode once within a unit period;
the first mode is a mode for charging the capacitor, in which the light emission driver outputs a first boost-on signal to the first switch and then outputs a first boost-off signal to the first switch in a period during which the light emission driver outputs a drive-off signal to the second switch;
the second mode is a mode for causing the laser diode to emit light, in which the light emission driver outputs a first drive-on signal to the second switch in a period during which the light emission driver outputs a second boost-off signal to the first switch; and
the first boost-on signal controls the first switch being turned on to switch the coil into the conductive state, the first boost-off signal controls the first switch being turned off to switch the coil into the non-conductive state, the drive-off signal controls the second switch being turned off to switch the laser diode into the non-conductive state, the first drive-on signal controls the second switch being turned on to switch the laser diode into the conductive state, and the second boost-off signal controls the first switch being turned off to switch the coil into the non-conductive state.

4. The laser emitter according to claim 1, further comprising:
a second series connector having a rectifier and a resistor being connected in series, the second series connector being connected in parallel to the laser diode, the rectifier configured to execute rectification for causing a current to flow from a cathode of the laser diode to an anode of the laser diode.

5. The laser emitter according to claim 4,
wherein the rectifier is a reverse conducting part of a transistor.

6. An optical ranging apparatus comprising:
a laser emitter including
a booster circuit configured to raise a DC voltage supplied by a DC power supply, the booster circuit including a coil, a first switch, a first diode, and a capacitor, the first switch configured to execute switchover between a conductive state and a non-conductive state of the coil, the first diode being connected in forward bias to the DC power supply,
a drive circuit including a laser diode and a second switch, the laser diode configured to be supplied by the DC voltage raised by the booster circuit, the second switch configured to execute switchover between a conductive state or non-conductive state of the laser diode,
a second diode being connected to the first switch in series, the second diode being connected in forward bias to the DC power supply, and
a light emission driver configured to control the booster circuit and the drive circuit;
a light receiver configured to receive reflection light reflected by an object to which laser light is emitted from the laser diode; and
a calculator configured to calculate a distance to the object based on a time duration from a moment where the laser light is emitted from the laser diode to a moment where the reflection light is received by the light receiver.
